(19) United States
(12) Patent Application Publication
(10) Pub. No.: US 2015/0273730 A1
(43) Pub. Date: Oct. 1, 2015

(54) MACHINING HEAD AND GROOVE MACHINING APPARATUS

(71) Applicant: MITSUBOSHI DIAMOND INDUSTRIAL CO., LTD., Osaka (JP)

(72) Inventor: Naoki KATAGIRI, Osaka (JP)

(21) Appl. No.: 14/663,894

(22) Filed: Mar. 20, 2015

(30) Foreign Application Priority Data
Mar. 27, 2014 (JP) 2014-065389
Dec. 26, 2014 (JP) 2014-265595

(51) Int. Cl. B28D 5/00; H01L 31/18; B26D 3/06

(52) U.S. Cl. CPC B28D 5/00; B26D 3/06; H01L 31/18

(57) ABSTRACT

A first head unit 31A has a tool holder 44 movably in a z axis direction on a base 42 through a linear guide 43. Similarly, a second head unit 31B has a tool holder 48 movably in the z axis direction on a base 46 through a linear guide 47. The interval Wa2 in an x axis direction between the tool and the linear guide of the head unit 31A and the interval Wb2 in the x axis direction between the tool and the linear guide of the head unit 31B are different from each other. When alternately arranging the head units 31A and 31B, displacing the positions of the linear guides 43 and 47 from each other to prevent interference makes it possible to narrow a pitch between the head units.

### BACKGROUND OF THE INVENTION

1. Field of the Invention

The present invention relates to a machining head and groove machining apparatus adapted to machine grooves in a thin film when manufacturing thin film solar cells.

2. Discussion of the Related Art

A manufacturing process for an integrated solar cell includes steps of stacking semiconductor thin films on a substrate and repeating patterning multiple time as described in, for example, Japanese Unexamined Patent Publication JPA2005-191167. This manufacturing process includes forming a metallic lower electrode layer on the brittle material substrate, and as a patterning P1, cutting and dividing the electrode layer into rectangles using a laser beam. Then, forming a P-type light absorption layer and a buffer layer on the patterned electrode layer gives an integrated semiconductor thin film. After that, as a patterning P2, mechanically scribing parts of the stack of the buffer layer and the P-type light absorption layer along lines slightly displaced from grooves formed as the patterning P1 is cut and divided into rectangles. Then a transparent conductive film made of metal oxide on the buffer layer is formed. Subsequently, as a patterning P3, mechanically scribing parts of the stack of the transparent conductive film, the buffer layer, and the P-type light absorption layer along lines slightly displaced from grooves formed as the patterning P2 is cut and divided into rectangles. The thin film solar cell is manufactured in this manner. For this purpose, it is necessary to slightly displace the lines formed as each of the patterning P2 and P3 from the lines formed as the patterning P1, and it is also necessary to form one hundred and several tens parallel grooves at pitches of, for example, approximately 5 mm in one substrate.

Japanese Unexamined Patent Publications JPA2011-155151 and JP-A2010-245255 disclose a scribing apparatus for solar cells. The scribing apparatus disclosed in JPA2011-155151 includes, on a base for a scribing head, a tool holder adapted to hold a machining tool, an air cylinder adapted to move the tool holder up and down, a spring adapted to cancel out the weight of the tool holder, and the like, and presses the tool against a workpiece while adjusting a load using the air cylinder. Also, JPA2010-245255 discloses the scribing apparatus that simultaneously performs scribing in multiple positions by attaching a number of heads to a sliding mechanism on a beam.

Further, a machining head in Japanese Unexamined Patent Publication JPA2014-8553 elastically holds a head by dividing a tabular member through a slit to provide the head, a main body, and a rod. JPA2014-8553 proposes that parallel arraying a number of machining heads with a tool attaching to a head of each of the machining heads makes it possible to perform scribing in parallel in a manufacturing process for thin film solar cells.

However, the head disclosed in JPA2011-155151 has a large width of approximately several tens mm because of a structure combining multiple members, and therefore it is difficult to make the head narrower than the current width. For this reason, there is a problem of being unable to make a head interval so narrow in the case of parallel arranging a number of heads as disclosed in JPA2010-245255. As a result, there is a problem of being unable to perform scribing at narrow intervals of, for example, 5 mm in a manufacturing process for solar cells to simultaneously form a number of scribed lines in parallel. Also, there is a problem that using a linear ball bearing as a vertical movement guide for the tool prevents stabilization of a tool position during machining due to allowance of the guide. Further, since the tool interval is not narrow, a number of cameras are necessary in order to keep the accuracy of a machining position. In addition, the machining head in JPA2014-8553 lacks in rigidity, and therefore has a problem of difficulty in keeping the accuracy of a machining position.

### SUMMARY OF THE INVENTION

The present invention is made in consideration of such problems of the conventional machining heads, and intends to provide a machining head that makes it possible to array a number of tools in parallel at narrow pitches and is for simultaneously forming a number of grooves in a thin film solar cell substrate, and a groove machining apparatus using the machining head.

The machining head of the present invention comprises: a plurality of first head units having first tools at fore ends respectively; a plurality of second head units having second tools at fore ends respectively; a frame to which said first and second head units alternately attach at a regular interval; and a driver adapted to respectively and independently drive said first and second tools of said first and second head units in a z axis direction, wherein each of said first head units comprises: a base that is fixed to said frame, a tool holder that holds said first tool at a fore end; and a linear guide that makes said tool holder of said first head units movable in said z axis direction with respect to said base of said first head units, each of said second head units comprises: a base that is fixed to said frame; a tool holder that holds said second tool at a fore end; and a linear guide that makes said tool holder of said second head units movable in the z axis direction with respect to said base of said second head units, said first and second head units respectively have mutually different intervals from said respective tools to said linear guides thereof in an x axis direction perpendicular to said z axis direction, and said frame alternately arranges said first and second head units so as to arrange said tools of the respective head units at regular intervals in a y axis direction, and displace positions of said linear guides of the respective head units in the x axis direction from each other.

Note that it is not necessary to limit the number of head units to two, and arranging three or more types of head units respectively having mutually different intervals from tools to linear guides while displacing the positions of mutually adjacent linear guides in an x axis direction from each other is also possible.

In the machining head of the present invention, said first and second head units may be arranged mutual combination on said frame in plus and minus positions in the x axis direction perpendicular to a y axis along which the tool holders are arranged.

The groove machining apparatus of the present invention comprises: a table that places a substrate; said machining head to which tools for groove machining attach; and a moving mechanism adapted to relatively move said table and said machining head in a horizontal plane, wherein said groove machining apparatus movies said machining head parallel to an upper surface of said substrate to form grooves in said substrate.

According to the present invention having such features, displacing the positions of linear guides of adjacent head blocks from each other makes it possible to narrow the interval between the adjacent head blocks when arranging head blocks in parallel. Accordingly, the head blocks can be arranged at the same intervals as a pitch between grooves to be machined, making it possible to simultaneously form a number of grooves in a thin film when manufacturing solar cells.

### BRIEF DESCRIPTION OF THE DRAWINGS

FIG. 1 is a perspective view of a groove machining apparatus according to embodiments of the present invention;

FIG. 2 is a front view of a machining head according to embodiment 1 of the present invention;

FIG. 3 is a bottom view of the machining head according to the present embodiment;

FIG. 4A is a side view of a first head block according to the present embodiment;

FIG. 4B is a side view of a second head block according to the present embodiment;

FIG. 5 is a side view illustrating the arrangement of a set of the two types of head blocks according to the present embodiment; and

FIG. 6 is a bottom view of a machining head according to embodiment 2 of the present invention.

### DESCRIPTION OF THE PREFERRED EMBODIMENTS

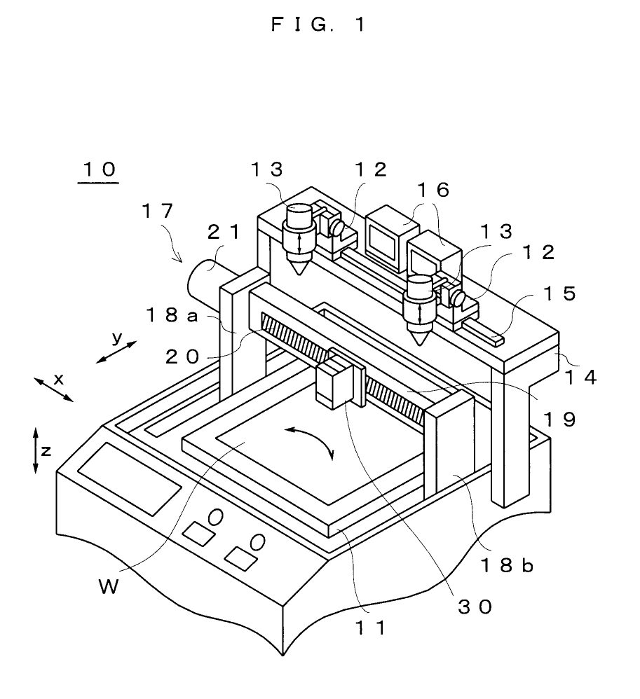

FIG. 1 is a perspective view illustrating an overall configuration of a groove machining apparatus according to embodiments of the present invention. In this view, the groove machining apparatus 10 includes a table 11 that places a thin film solar cell substrate W serving as a machining target on an xy plane thereof. The table 11 is movable in a y direction in FIG. 1 in the horizontal plane (xy plane), and also rotatable at an arbitrary angle in the horizontal plane.

Above the table 11, cameras 13 respectively attach to two bases 12. Each of the bases 12 is movable along a guide 15 extending in an x direction on a supporting base 14. The two cameras 13 are movable up and down, and monitors 16 respectively display corresponding images photographed by the cameras 13.

A bridge 17 provided above the table 11 has a pair of supporting columns 18a and 18b, a guide bar 19 provided between the supporting columns in the x axis direction, and a motor 21 adapted to drive a guide 20 formed in the guide bar 19. The bridge 17 holds a machining head 30 movably along the guide 20 in the x direction in the horizontal plane. Note that the guide 20 and the motor 21 provided to the bridge 17 constitute moving mechanism adapted to relatively move the machining head in the x axis direction in the horizontal plane.

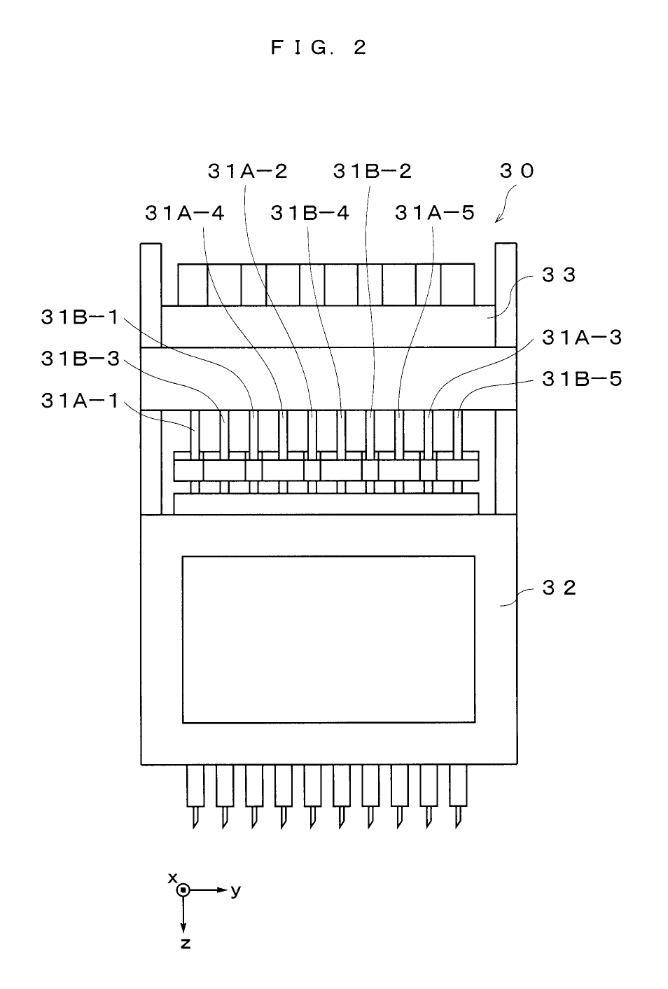

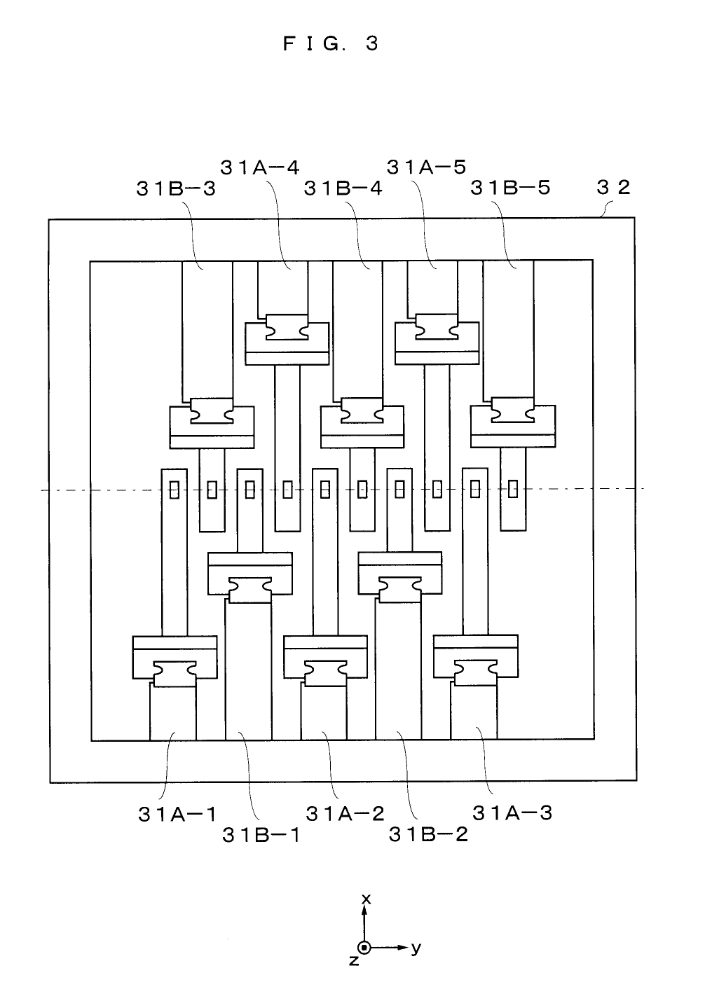

Next description is on the machining head 30 according to embodiment 1 of the present invention. FIG. 2 is a front view of the machining head 30, and FIG. 3 is a bottom view of the machining head 30. As these views illustrate, the machining head 30 has a plurality of head units adjacently arranged at regular intervals. This embodiment assumes, for example, 10 head units 31A-1 to 31A-5, and 31B-1 to 31B-5 arranged at intervals of 5 mm. As FIGS. 2 and 3 illustrate, these head units are attached to a frame 32. A cylinder block 33 is also attached to the flame 32. The cylinder block 33 includes cylinders of which the number corresponds to the number of the heads, in this embodiment, 10 cylinders, and each of the cylinders has a duct adapted to independently supply air. Also, supplying air to the respective cylinders makes pistons inside the cylinders movable in a z axis direction. Further, the pistons are respectively connected with the head units 31A-1 to 31A-5, and 31B-1 to 31B-5. Between the respective head units and the frame 32, unillustrated springs are stretched.

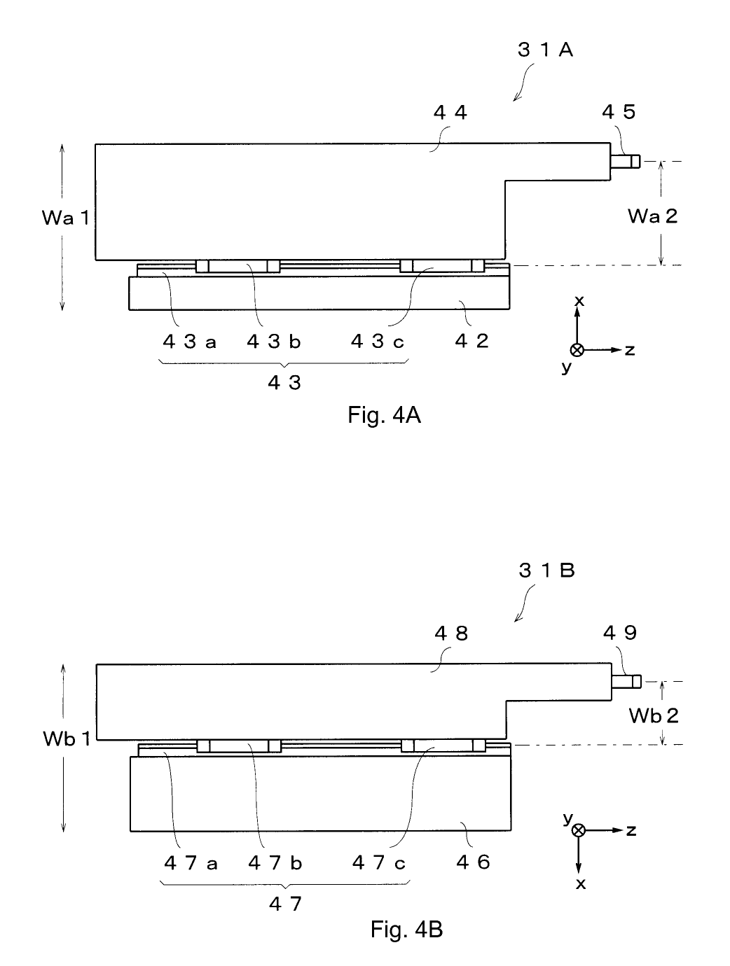

Subsequent description is on the configuration of each of the head units. In order to arrange the respective head units at the narrow intervals, this embodiment employs the head units 31A of a first type and the head units 31B of a second type, between which the position of a linear guide is different. As FIG. 4A illustrates, each of the first head units 31A has a tool holder 44 movably in the z axis direction on a thin base 42 through linear guide 43. The linear guide 43 includes: a rail 43a that extends in the z axis direction along the upper surface of the base 42; and a pair of sliders 43b and 43c that slides on the rail in the z axis direction. The sliders 43b and 43c are connected to the tool holder 44. This makes it possible to move the tool holder 44 freely in the plus and minus z axis directions with respective to the base 42. To the right fore end of the tool holder 44, as the view illustrates, a first tool 45 attaches.

On the other hand, as FIG. 4B illustrates, each of the second head units 31B has a tool holder 48 movably in the z axis direction on a base 46 thicker than the base 42 through a linear guide 47. The linear guide 47 includes: a rail 47a that extends in the z axis direction along the upper surface of the base 46; and a pair of sliders 47b and 47c that slides on the rail in the z axis direction. The sliders 47b and 47c are connected to the tool holder 48. This makes it possible to move the tool holder 48 freely in the plus and minus z axis directions with respect to the base 46. To the right fore end of the tool holder 48, as the view illustrates, a second tool 49 attaches. The tool 45 and 49 are members having a width of several tens μm and a tip slightly thinned in order to pattern a thin film substrate such as a solar cell substrate. Note that the cylinder block, cylinders, and pistons provided on and above the frame constitute a driver adapted to drive the tools of the head units in the z axis direction.

As FIG. 4A illustrates, it is here assumed that the thickness of the whole of the base 42, the linear guide 43, and the tool holder 44 in the x axis direction is Wa1, and the distance between the centers of the tool 45 and the linear guide 43 in the x axis direction is Wa2. Also, as FIG. 4B illustrates, it is assumed that the thickness of the whole of the base 46, the linear guide 47, and the tool holder 48 in the x axis direction is Wb1, and the distance between the centers of the tool 49 and the linear guide 47 in the x axis direction is Wb2. The base 42 has smaller thickness in the x axis direction as compared with the base 46, and the tool holder 44 has larger thickness in the x axis direction as compared with the tool holder 48. However, it is assumed that the thicknesses Wa1 and Wb1 respectively including the bases, the linear guides, and the tool holders of the head units 31A and 31B in the x axis direction are the same. On the other hand, the intervals between the respective tool and linear guide are different between the head units 31A and 31B. For example, in FIG. 4A and FIG. 4B, Wa2 is larger than Wb2.

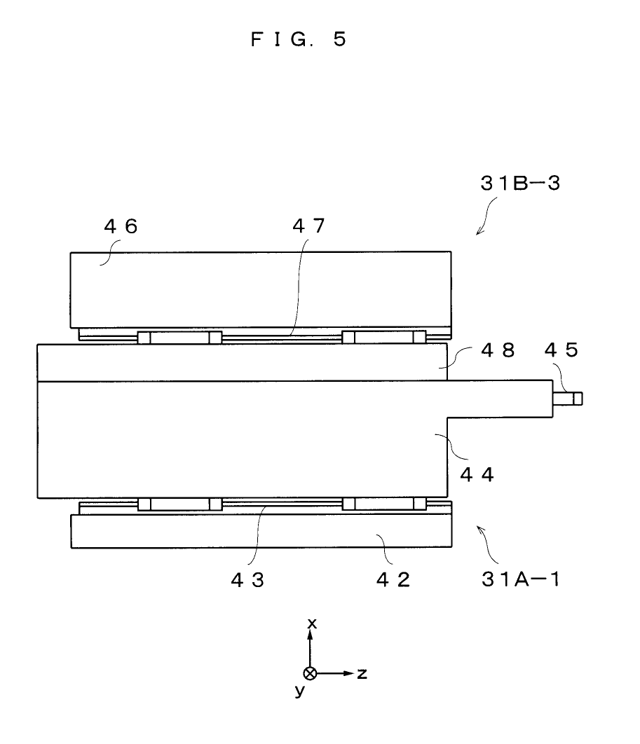

As FIG. 3 illustrates, the machining head 30 of the present embodiment alternately arranges the head units 31A and 31B so as to align the positions of the tools in the y axis direction. Further, the machining head 30 arranges the head units inverting the head units symmetrically with respect to the centerline that passes through the center positions of the respective tools as indicated by a dashed-dotted line, and is parallel to the y axis, and aligns the tool positions. That is, on the lower side of the dashed-dotted line passing through the center positions of the respective tools in FIG. 3, the machining head 30 arranges the head units 31A-1, 31B-1, 31A-2, 31B-2, and 31A-3. On the other hand, on the upper side of the dashed-dotted line in FIG. 3, the machining head 30 arranges the head units 31B-3, 31A-4, 31B-4, 31A-5, and 31B-5. Further, the machining head 30 alternately arranges the upper and lower head units so as to make the intervals between adjacent tools at the tips equal to the constant width. In this embodiment, the width is 5 mm. FIG. 5 illustrates the head units 31A-1 and 31B-3 present on the leftmost side in FIG. 3. In addition, the frame 32 holds the bases of the head units.

As described, in the present embodiment, alternately arranging the first and second head units 31A and 31B, and further alternately arranging the head units from different directions along the x axis direction prevents the interference between adjacent linear guides having the large width in the y axis direction to narrow the pitch between adjacent tools. Accordingly, it is only necessary to set the difference between the intervals between the tools and the linear guides of the two type of head units 31A and 31B to a level that prevents the interference between adjacent linear guides.

Meanwhile, in the case of using the machining head to machine grooves, the first step is, as FIG. 1 illustrates, to arrange the thin film solar cell substrate on the table 11. The next step is to move the machining head 30 to one end in the x axis direction, and adjust air to be supplied to the cylinders of the cylinder block to control the positions of the tools of the respective head units in the z axis direction. This makes it possible to independently set a load on each of the tools when manufacturing a solar cell. The subsequent step is to drive the motor 21 and move the machining head 30 along the x axis direction to scribe the thin film solar cell substrate W while applying optimum loads, making it possible to simultaneously form a number of grooves. The step after completion of the formation of the grooves in the x axis direction is to slightly move up the respective head blocks, to displace the table 11 in the y axis direction, and to move down the respective head blocks again to repeat the groove machining. In doing so, the patterning P1, P2, and P3 can be formed at the narrow intervals.

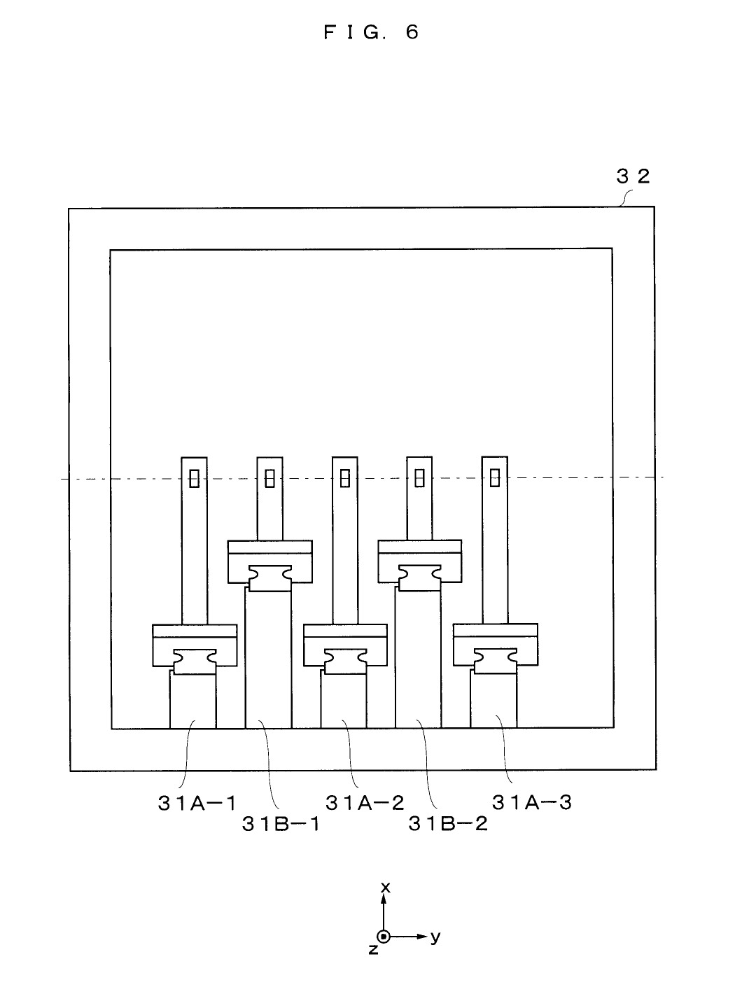

Next description is on embodiment 2 of the machining head of the present invention. Embodiment 1 described above alternately arranges the two types of head units 31A and 31B in both of the plus and minus x axis directions as FIG. 3 illustrates. However, embodiment 2 arranges the above-described two types of head units 31A and 31B only in any one of the plus and minus x axis directions. FIG. 6 illustrates an example of the arrangement, and specifically illustrates an example of arranging the head units 31A-1, 31B-1, 31A-2, 31B-2, 31A-3, and 31B-2 only on one side in the x axis direction. In this case as well, displacing the positions of linear guides of the head units from each other makes it possible to arrange the head units while narrowing the intervals between adjacent tools.

Also, the groove machining apparatus of this embodiment forms grooves in a solar cell substrate by moving the machining head in the x axis direction, but may machine grooves while moving the table in the y axis direction with the tools rotated at 90 degrees and held. In such a case, moving mechanism adapted to move the table in the y axis direction serves as the moving mechanism adapted to relatively move the table and the machining head in the horizontal plane.

Embodiments 1 and 2 alternately arrange the two types of head units having mutually different linear guide positions; however, in place of this, the present invention may employ three or more types of head units having mutually different linear guide positions. Adjacently arranging at least two types of head units having mutually different linear guide positions, i.e., having mutually different intervals between tools and linear guides so as to make linear guide positions of adjacent head units different makes it possible to arrange tools at narrow intervals as with embodiments 1 and 2.

Since a number of tools are attachable at narrow pitches by attaching a number of machining heads in parallel, the machining head is preferably usable for a groove machining apparatus for solar cells adapted to simultaneously form a number of grooves.

The text of Japanese application No. 2014-065389 filed on Mar. 27, 2014 and the text of Japanese application No. 2014-265595 filed on Dec. 26, 2014 are hereby incorporated by reference.

What is claimed is:

1. A machining head comprising:
a plurality of first head units having first tools at fore ends respectively;
a plurality of second head units having second tools at fore ends respectively;
a frame to which said first and second head units alternately attach at a regular interval; and
a driver adapted to respectively and independently drive said first and second tools of said first and second head units in a z axis direction, wherein
each of said first head units comprises:
a base that is fixed to said frame,
a tool holder that holds said first tool at a fore end; and
a linear guide that makes said tool holder of said first head units movable in said z axis direction with respect to said base of said first head units,
each of said second head units comprises:
a base that is fixed to said frame;
a tool holder that holds said second tool at a fore end; and
a linear guide that makes said tool holder of said second head units movable in the z axis direction with respect to said base of said second head units,
said first and second head units respectively have mutually different intervals from said respective tools to said linear guides thereof in an x axis direction perpendicular to said z axis direction, and
said frame alternately arranges said first and second head units so as to arrange said tools of the respective head units at regular intervals in a y axis direction, and displace positions of said linear guides of the respective head units in the x axis direction from each other.

2. The machining head according to claim 1, wherein
said first and second head units are arranged mutual combination on said frame in plus and minus positions in the x axis direction perpendicular to a y axis along which the tool holders are arranged.

3. A machining head comprising:
a plurality of head units having tools at fore ends respectively;
a frame to which said head units attach at a regular interval; and
a driver adapted to respectively and independently drive said tools of said head units in a z axis direction, wherein
each of the head units comprises:
a base that is fixed to said frame;
a tool holder that holds said tool at a fore end; and
a linear guide that makes said tool holder movable in the z direction with respect to said base,
said head units include at least two types of head units respectively having mutually different intervals from said tools to said linear guides thereof in an x axis direction perpendicular to a z axis, and
said frame adjacently arranges said head units respectively having the mutually different intervals from said tools to said linear guides so as to arrange said tools of said respective head units at a regular interval in a y axis direction, and displace positions of said linear guides of the adjacent head units in the x axis direction from each other.

4. The machining head according to claim 3, wherein
said at least two types of head units are arranged in combination on the frame in plus and minus positions in the x axis direction perpendicular to a y axis along which the tool holders are arranged.

5. A groove machining apparatus comprising:
a table that places a substrate;
said machining head according to claim 1, to which tools for groove machining attach; and
a moving mechanism adapted to relatively move said table and said machining head in a horizontal plane, wherein
said groove machining apparatus movies said machining head parallel to an upper surface of said substrate to form grooves in said substrate.

6. A groove machining apparatus comprising:
a table that places a substrate;
said machining head according to claim 2, to which tools for groove machining attach; and
a moving mechanism adapted to relatively move said table and said machining head in a horizontal plane, wherein
said groove machining apparatus movies said machining head parallel to an upper surface of said substrate to form grooves in said substrate.

7. A groove machining apparatus comprising:
a table that places a substrate;
said machining head according to claim 3, to which tools for groove machining attach; and
a moving mechanism adapted to relatively move said table and said machining head in a horizontal plane, wherein
said groove machining apparatus movies said machining head parallel to an upper surface of said substrate to form grooves in said substrate.

8. A groove machining apparatus comprising:
a table that places a substrate;
said machining head according to claim 4, to which tools for groove machining attach; and
a moving mechanism adapted to relatively move said table and said machining head in a horizontal plane, wherein
said groove machining apparatus movies said machining head parallel to an upper surface of said substrate to form grooves in said substrate.
